(19) United States
(12) Patent Application Publication
(10) Pub. No.: US 2003/0107033 A1
(43) Pub. Date: Jun. 12, 2003

(54) Trilayer heterostructure junctions

(76) Inventors: Alexander Tzalenchuk, Goteborg (SE); Zdravko G. Ivanov, Goteborg (SE); Miles F. H. Steininger, West Vancouver (CA)

Correspondence Address: Gary S. Williams, Pennie & Edmonds LLP, 3300 Hillview Avenue, Palo Alto, CA, 94304, US

(21) Appl. No.: 10/006,787

(22) Filed: Dec. 6, 2001

(51) Int. Cl. H01L 29/06

(52) U.S. Cl. 257/31; 257/30

(57) ABSTRACT

In accordance with embodiments of the present invention, a junction of an unconventional superconductor, an intermediate material, and a conventional superconducting material is presented. In some embodiments, the resulting junction is in the c-axis direction of the orthorhombic unconventional superconductor. Alternatively, the junction is in the a-b plane direction. Interface junctions according to embodiments of the present invention may be used in super low inductance qubits (SLIQs) and in permanent readout superconducting qubits (PRSQs), can form the basis of quantum registers, and can allow for parity keys or other devices made from conventional superconducting material to be attached to qubits made from unconventional superconducting material or vice versa. Coherent tunnel junctions according to embodiments of the present invention may be used to form parity keys or coherently couple two regions of a superconducting material.

### BACKGROUND

1. Field of the Invention

This invention relates to structures that have quantum coherence, and more particularly to superconducting quantum computing.

2. Description of Related Art

The Josephson effect was first described by Brian Josephson in 1962; see e.g. B. D. Josephson, Phys. Lett. 1:251 (1962). Josephson proposed in particular that non-dissipating current would flow from one superconductor to another through a thin insulating layer. This was quickly verified experimentally. The Josephson effect was generalized to all weak links in a superconductor and found practical application in a device known as a superconducting quantum interference device (SQUID). The current and voltage of a superconducting loop with two small insulating gaps would behave in a previously unexpected way dependent on the magnetic flux enclosed in the loop. SQUIDs are useful for sensitive measurement and in the creation of magnetic fields. For example, see chapter 1 of A. Barone and G. Paternò, Physics and Applications of the Josephson Effect, John Wiley & Sons, New York, 1982.

Two types of superconductors are regularly used: conventional superconductors and unconventional superconductors. The most important phenomenological difference between the unconventional superconductors and conventional superconductors regards the orbital symmetry of the superconducting order parameter. In the unconventional superconductors, the pair potential changes sign depending on the direction in momentum space. This was experimentally confirmed; see e.g. C. C. Tsuei and J. R. Kirtley, Rev. Mod. Phys. 72, 969 (2000). Further, it was discovered that in orthorhombic materials such as YBa₂Cu₃Oₓ (YBCO) there existed a significant subdominant order parameter mode that is spherical in momentum space (s-wave); see K. A. Kouznetsov et al, Phys. Rev. Lett. 79, 3050 (1997). Effects of this pairing were known for years previous to these insights. The coherence length of the unconventional superconductor is not isotropic. The coherence length in the c-axis direction is much less than in the a and b directions. The critical current is much smaller in the c-axis direction.

The coherence length, in all directions, of an unconventional superconductor is small enough for a weak link to form at any junction. Given that the Josephson effect is present in all weak links, the short coherence length is an issue in superconducting structures. These weak links are interruptions of the translational symmetry of the bulk with distance across on the same scale as the coherence length of the superconducting material. This includes the following weak links: grain boundaries, insulating gaps, tunneling junctions, constrictions, and any locations where the amplitude of the order parameter of the superconductor is diminished. Therefore any small interruption of a superconducting material or interface of two different superconductors is a Josephson junction. Avoiding the formation of weak links where Josephson junctions are not intended can make the fabrication of devices difficult.

Superconducting SETs are generally made from conventional superconductors. Efforts to make them from unconventional superconducting materials have not been fully successful. See, e.g., S. E. Kubatkin et al JETP Lett. 63, pp126-132, (1996) and A. Tzalenchuk's poster from SQUID 2001 to be published in Physica C. The oscillations of an unconventional superconducting material SET have only a single charge periodicity, not both a single and a double charge period. Both effects are useful in superconducting quantum computing. Supercurrent is made up of Cooper pairs, a mechanism for controllable switching of supercurrent is important. Thus there is a need for an unconventional, controllable supercurrent switch.

Contemporary superconducting qubit designs have leads made of conventional superconducting material, unconventional superconducting material or one of both. Interface junctions, that is, Josephson junctions between a conventional superconductor layer and an unconventional superconductor layer, have high Josephson energy that allows for good contact between the unconventional and the conventional superconductor and vice versa. Junctions constructed with differing ratios of charging energy to Josephson energy can be attached to a qubit as part of a parity key. Accordingly, it is desirable to create junctions using a method that has high precision with a tunable tunneling effect.

Interface junctions with the necessary function are known, but suffer from deficiencies that prevent their use in superconducting quantum computing. They are far larger in area than the mesoscopic devices that they need attach to, creating a small junction. This is a severe limitation as size is often an enabling feature in quantum computers built from superconducting material. Certain components must be mesoscopic. Therefore, to implement quantum computing structures, Josephson junctions between conventional and unconventional superconductors are necessary, and no junction in the prior art suffices.

### SUMMARY

In accordance with the present invention, a Josephson junction is presented. In some embodiments, the junction includes an unconventional superconductor, an intermediate material, and a conventional superconducting material. In some embodiments, the resulting junction is in the c-axis direction of an orthorhombic unconventional superconductor. Alternatively, the junction may be in the a-b plane direction.

Josephson junctions according to embodiments of the present invention may be used in super low inductance qubits (SLIQs) and in permanent readout superconducting qubits (PRSQs), can form the basis of quantum registers, and can allow for parity keys or other devices made from conventional superconducting material to be efficiently coupled to qubits made from unconventional superconducting material. Further, embodiments of the invention may be applicable to any superconducting electronic situation where coherent transport between to bulk unconventional superconductors is needed.

In some embodiments, an unconventional superconductor having non-zero angular momentum pairing and having its c-axis oriented in the [001] direction is placed on a substrate. A conventional superconductor having a dominant mode that has zero angular momentum pairing is placed above the unconventional superconductor. Another material such as a normal metal or an insulator separates the conventional and unconventional superconductors to form a heterostructure (or heterojunction) to which electrodes may be attached.

Multiple methods of fabrication are detailed. Relative sizes of physical parameters needed for operation are introduced. Different materials as intermediate layer are introduced. The usage of various embodiments of heterojunctions in quantum computing structures is outlined.

### BRIEF DESCRIPTION OF THE DRAWINGS

FIG. 1A illustrates a c-axis embodiment of the present invention.

FIG. 1B illustrates an a-b plane embodiment of the present invention.

FIG. 1C illustrates a hybrid c-axis and a-b plane embodiment of the present invention.

FIGS. 2A-2D illustrate a method of fabricating a c-axis heterostructure as shown in FIG. 1A.

FIGS. 2F-2H illustrate a method of fabricating any of the embodiments shown in FIGS. 1A-1C.

FIGS. 2K-2M illustrate another method of fabricating a c-axis junction as shown in FIG. 1A.

FIGS. 2P-2Q illustrate a method of fabricating an a-b plane junction as shown in FIG. 1B and a hybrid heterostructure as shown in FIG. 1C.

FIGS. 3A-3C illustrate PRSQ structures incorporating embodiments of the present invention.

FIGS. 4A-4B illustrate multiple junctions in a quantum register.

FIGS. 5A-5B illustrate even and odd numbers of junctions with a pi junction in a loop

FIG. 6 illustrates a coherent connection between two unconventional superconductors.

### DETAILED DESCRIPTION

In accordance with the present invention, Josephson junctions using conventional and unconventional superconductors are presented. In some embodiments, junctions according to the present invention may be interface junctions with good electrical contact between an unconventional and a conventional superconducting material. Alternatively, junctions according to the present invention may be used to form coherent tunnel heterostructure junctions suitable for use in superconducting Single Electron Transistors (SETs). Junctions in accordance with the present invention may have an intermediate material that separates the two superconductors. In some embodiments, the junctions have current flowing in the direction of the largest lattice vector (c) of one of the superconductors, which may be orthorhombic. Alternatively, the current can flow orthogonally to the c-direction, in the direction of the a-b plane. The junctions can be incorporated as part of, or appendages of, larger devices such as a qubit in a quantum computer or a SQUID in sensor or metrology applications.

Embodiments of junctions according to the present invention can be made into tunnel junctions by the use of a dielectric layer as the intermediate layer separating the two superconductors. If the junction has high critical current it will be a standard Josephson junction. If the Coulomb energy is high, the junction can be used as the tunnel junction in a SET. The SET with parity effects was theoretically proposed by K. A. Matveev et al, Phys. Rev. Lett. 70, 2946 (1993) which is incorporated by reference. Later the device was realized. P. Joyez et al, Phys. Rev. Lett. 72:15 (1994), which is incorporated by reference, describes operation and manufacture of one type of single electron transistor.

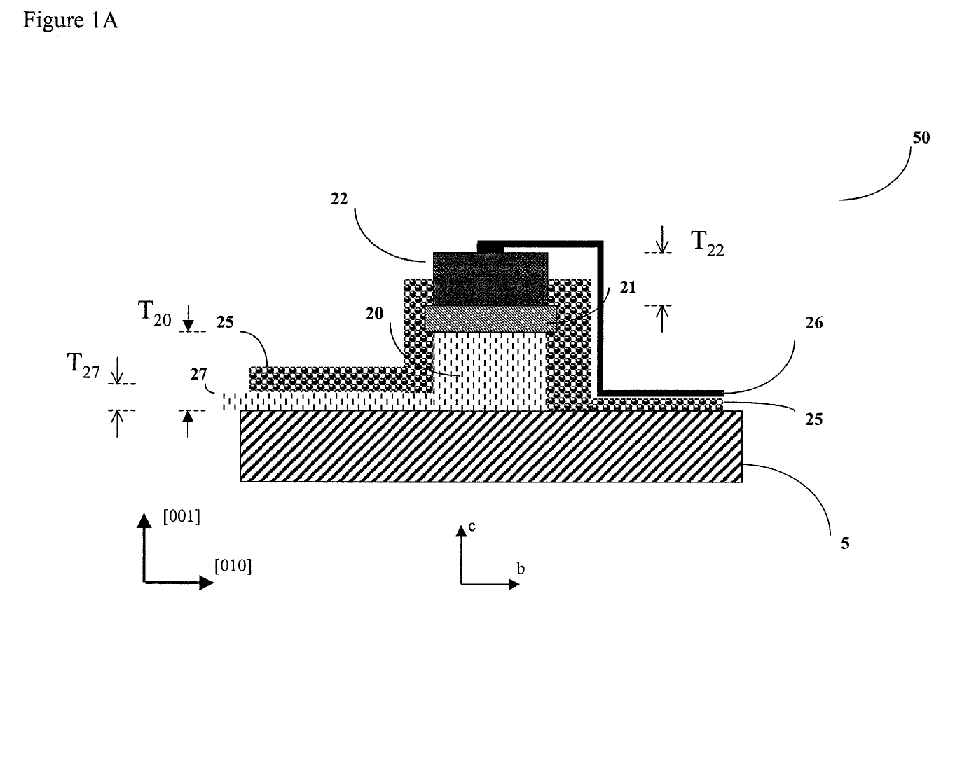

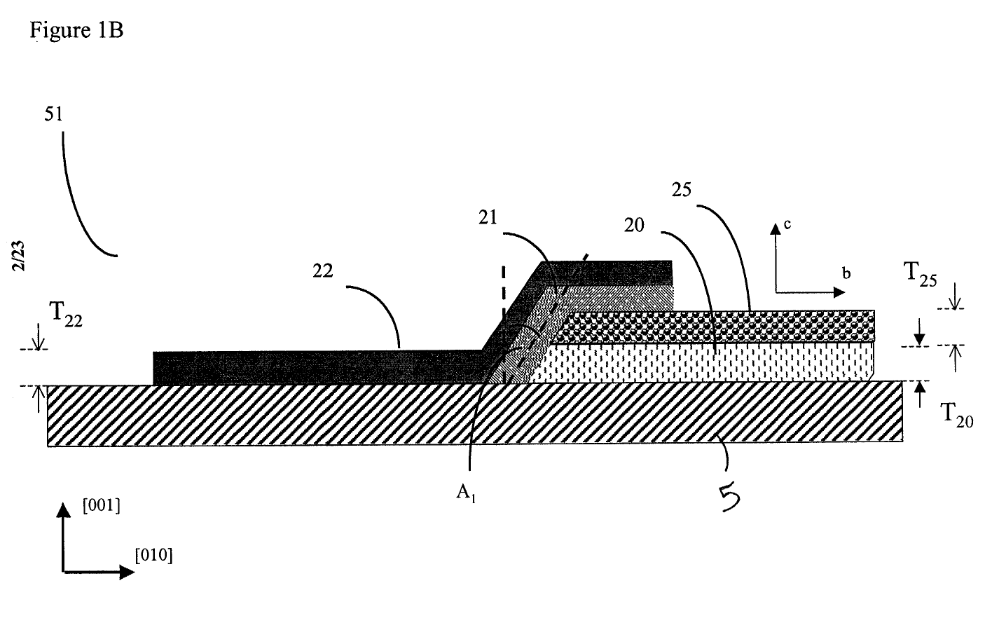

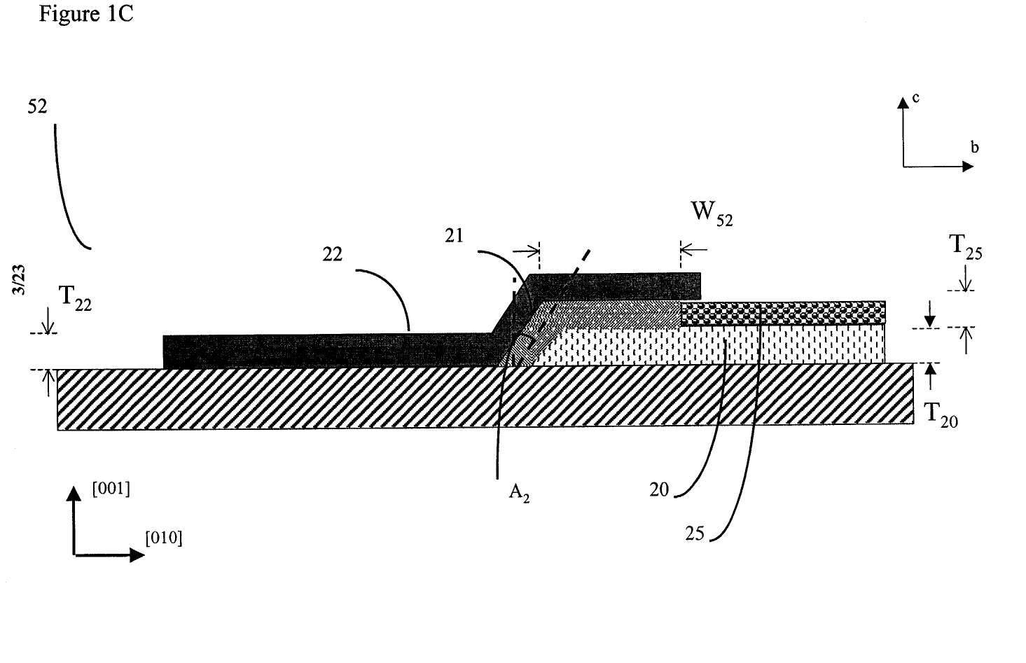

FIG. 1A illustrates an embodiment of a junction according to the present invention where coupling occurs in the direction of the largest lattice vector (c-axis) of an orthorhombic unconventional superconductor. FIG. 1A shows a trilayer, c-axis, heterostructure 50. Substrate 5 may be, for example, an insulator such as MgO, LaAlO₃ or sapphire, or a conductor or semiconductor such as silicon covered with a suitable insulator. An unconventional superconductor 20 is grown over substrate 5. Unconventional superconductor 20 may be, for example, a high T_{c} cuprate such as, for example, YBa₂Cu₃Oₓ (YBCO). Above unconventional superconductor 20, an intermediate layer 21 of insulating material or normal metal such as, for example, gold is deposited. The third layer in the trilayer heterostructure is a conventional superconductor 22. Conventional superconductor 22 may be, for example, niobium, aluminum, or lead. An insulating layer 25 may cover portions of the structure. Electrodes 26 and 27 connect to conventional superconductor 22 and unconventional superconductor 20. As is clear from FIG. 1A, the conventional superconductor 22/intermediate material 21/unconventional superconductor 20 junction is oriented in the direction of the c-axis of unconventional superconductor 20.

FIG. 1B illustrates an embodiment of the invention where the coupling occurs in the directions normal to the c-axis, the a-b plane. FIG. 1B shows a ramp type trilayer heterojunction 51. As in FIG. 1A, an unconventional superconductor 20 is formed on a substrate 5. Adjacent to unconventional superconductor 20 is intermediate layer 21, either an insulating material or normal metal. Conventional fabrication techniques create a junction with an angle A₁ from the substrate normal that may be non zero. Angle A₁ depends on the etch used to form the mesa and the composition of superconductors 20 and 22. A usual value for angle A₁ is about 30°. A perpendicular junction (i.e. where angle A₁ is zero) may also be formed, though junction 51 is usually slightly angled. A conventional superconductor 22 is placed on substrate 5 adjacent to layer 21. As is clear from FIG. 1B, the conventional superconductor 22/intermediate material 21/unconventional superconductor 20 junction is oriented in the direction of the b-axis of unconventional superconductor 20.

In the embodiments illustrated in FIGS. 1A-1C, superconducting layer 20 may have a thickness T₂₀ on the order of about 75 to about 200 nm. Conventional superconductor 22 may have a thickness T₂₂ of about 100 to 300 nm. Junction 50 of FIG. 1A and junction 51 of FIG. 1B may be either SND, meaning that the intermediate layer is a normal metal, or SID, meaning that the intermediate layer is an insulating layer. In embodiments where intermediate layer 21 is a normal metal, intermediate layer 21 may have a thickness less than 20 nm. In embodiments where intermediate layer 21 is an insulating layer, intermediate layer 21 may have a thickness of a few nanometers to tens of nanometers. Optionally, conventional superconductor 22 may be both adjacent to unconventional superconductor 20 and intermediate layer 21 heterostructure and above them, so long as unconventional superconductor 20 and conventional superconductor 22 are not in contact. The thickness of insulating layer 25 is large enough to reduce the stray tunneling amplitude between unconventional superconductor 20 and conventional superconductor 22 to a negligible level, generally about five to ten times the coherence length.

The coherence length is less for the c-axis than the a-axis or b-axis, thus for a given area, the transparency of junction 50 shown in FIG. 1A is less than the transparency of junction 51 shown in FIG. 1B. Transparency refers to the amount of superconducting current a junction is capable of supporting. Since the transparency of junction 50 of FIG. 1A is less than that of junction 51 of FIG. 1B, a junction with the geometry shown in FIG. 1A must be larger than a junction such as junction 51 shown in FIG. 1B to support the same amount of current.

FIG. 1C illustrates a hybrid junction 52. Here both a-b plane and c-axis couplings exist, because superconductor 22 overlies portions of intermediate layer 21 and superconductor 20 in both the c-axis and a-b plane directions. This structure is similar in structure but not function to bistable Josephson junction structures disclosed in U.S. application Ser. No. 09/479,336, titled “Qubit Using A Josephson Junction Between S-Wave And D-Wave Superconductors,” which is incorporated herein by reference. The junction shown in FIG. 1C is optionally an interface junction (meaning intermediate layer 21 is a normal metal) or a tunnel junction (meaning intermediate layer 21 is an insulator). Like junctions 50 and 51 shown in FIGS. 1A and 1B respectively, junction 52 shown in FIG. 1C has an unconventional superconductor 20, an intermediate layer 21, and a conventional superconductor 22. Further junction 52 has an overlap of layers 21 and 22 onto unconventional superconductor 20. This overlap distance W₅₀ may be compared to height T₂₀ to estimate the relative coupling in each of the b- and c-directions, though the amount of coupling in each direction also depends on the transparencies of the junctions in each direction. By varying the amount of contact in each of the c- and b-directions, the type of coupling may be changed. However, as the b- (or a-) direction is more transparent than the c-direction, the ratio of coupling is not equal to the ratio of the areas. The junction is at an angle A₂ with the substrate normal. Angle A₂ may be zero.

Junctions 50, 51, and 52 of FIGS. 1A-1C respectively each have a length, which is the length of overlap of superconductors 20 and 22, in the planes of FIGS. 1A-1C. The width of junctions 50, 51, and 52 is the width of overlap of superconductors 20 and 22, perpendicular to the plane of FIGS. 1A-1C. Generally, the width of a junction is less than the junction's length. The area of junctions 50, 51, and 52 is simply the length multiplied by the width. In general, a c-axis junction such as that illustrated in FIG. 1A will have the largest area and an a-b plane junction such as that illustrated in FIG. 1B will have the smallest area. Hybrid junction 52 of FIG. 1C generally has an area less than a c-axis junction and greater than an a-b plane junction.

In some embodiments of junction 50 of FIG. 1A, the area may be between about 0.01 μm² and about 0.1 μm². The length of junction 50 may be, for example, about 0.5 μm and the width of junction 50 may be, for example, about 0.1 μm, yielding an area of about 0.05 μm². In junction 51 of FIG. 1A, the area may be between about 0.01 μm² and about 0.02 μm². The length of junction 51 may be, for example, about 0.2 μm and the width of junction 51 may be, for example, about 0.1 μm, yielding an area of about 0.02 μm².

For some embodiments, the quality of the junctions 50-52 shown in FIGS. 1A-1C should be high. Particularly, the roughness of the material interfaces may be minimized. The smoothness prevents current from flowing in the direction other than the direction intended by the geometry of the junction. The physical values of roughness for surfaces may be an absolute variance of less than about 3 nm for elevations and depressions separated by hundreds of nanometers; depending on what method of fabrication was used and what form intermediate layer 21 takes. Especially in c-axis junctions 50, smoother layers yield junctions where the intended coupling is the only coupling across the junction. Further, given the anisotropy of the properties of many unconventional superconductors, the resistance of smooth junctions is greater.

The critical current I_{c} of a junction is the value above which the superconductor can not sustain supercurrent. It is also the maximum current level in the DC Josephson effect. Exceeding this value will introduce a resistive term (related to quasi particles) that will prevent a qubit from being in its intended superposition of states. The Josephson energy E_{J} of the junction is proportional to I_{c}. In the creation of interface junctions I_{c}, and therefore E_{J}, may be maximized. The value of the Josephson energy may be such that it is energetically favorable to have the phase of the order parameters, on either side of the interface junction, equal.

The normal resistance of a SND junction may, in some embodiments of junctions 50-52, be minimized. For an example when superconductor 20 is YBCO, intermediate layer 21 is gold, and superconductor layer 22 is niobium, resistance in the YBCO/Nb interface may be about 10⁻² Ωcm² and resistance in the Au/Nb interface may be about 10⁻⁶ Ωcm². These values change with materials used in the examples and are varied to optimize (i.e. reduce) decoherence.

For Josephson junctions there exists a length that the distance between superconductors (the thickness of intermediate layer 21) cannot greatly exceed, or negligible current through the junctions will result. The thickness T₂₁ and details of transport across layer 21 differ with material. The characteristic lengths all have different names and values, which are collectively called coherence lengths and are further discussed below. The coherence length, ξ, of the superconductor is important for insulating barriers, where tunneling is the current transport mechanism. In clean metallic weak links, the correlation length of the metal, [symbol] ν_{F}/kT matters, where ν_{F} is the Fermi velocity, k the Boltzman constant and T is temperature. In dirty links, where the current transmission across the junctions is diffuse, the characteristic length is \sqrt{ [symbol]D/kT}, were D is an empirical diffusion coefficient.

When a junction is formed with an insulator as intermediate layer 21, the junction may have resistance that is high enough and capacitance that is low enough to create a tunnel junction. Capacitance is proportional to the dielectric constant of the insulator in layer 21, and area of the junction. Resistance is inversely proportional to area. Therefore reduction of junction scale would suffice; an area of approximately 0.05 μm² (μm²=10⁻¹² meters square) is appropriate for a c-axis junction. Less area is required for all others, as described above.

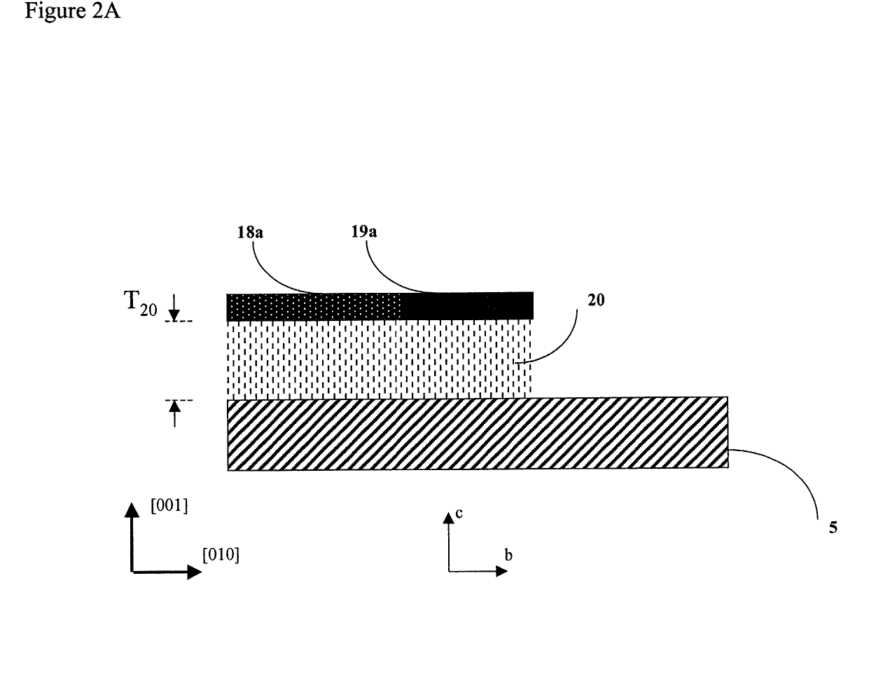

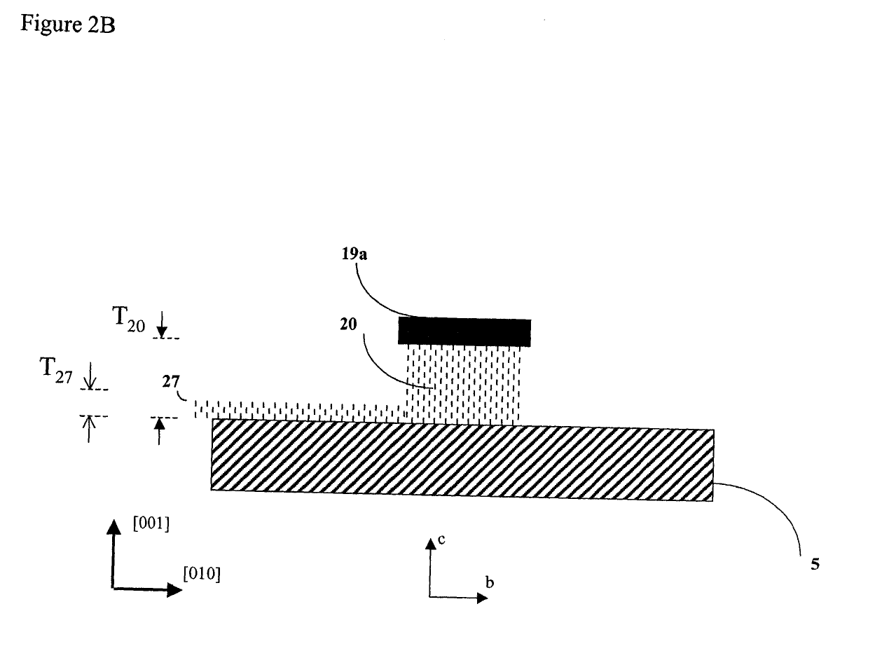

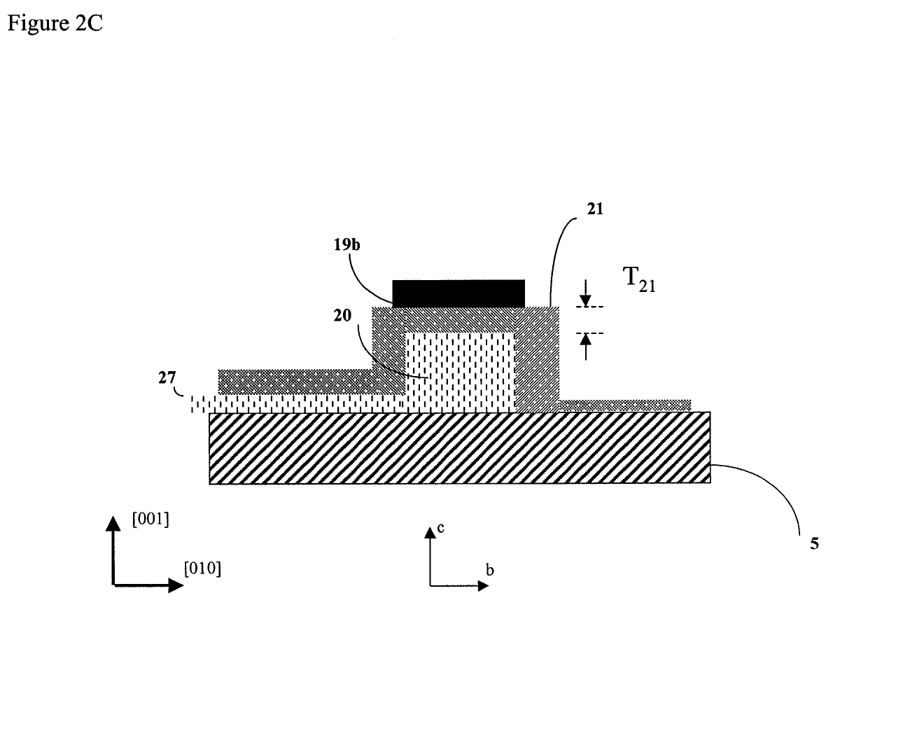

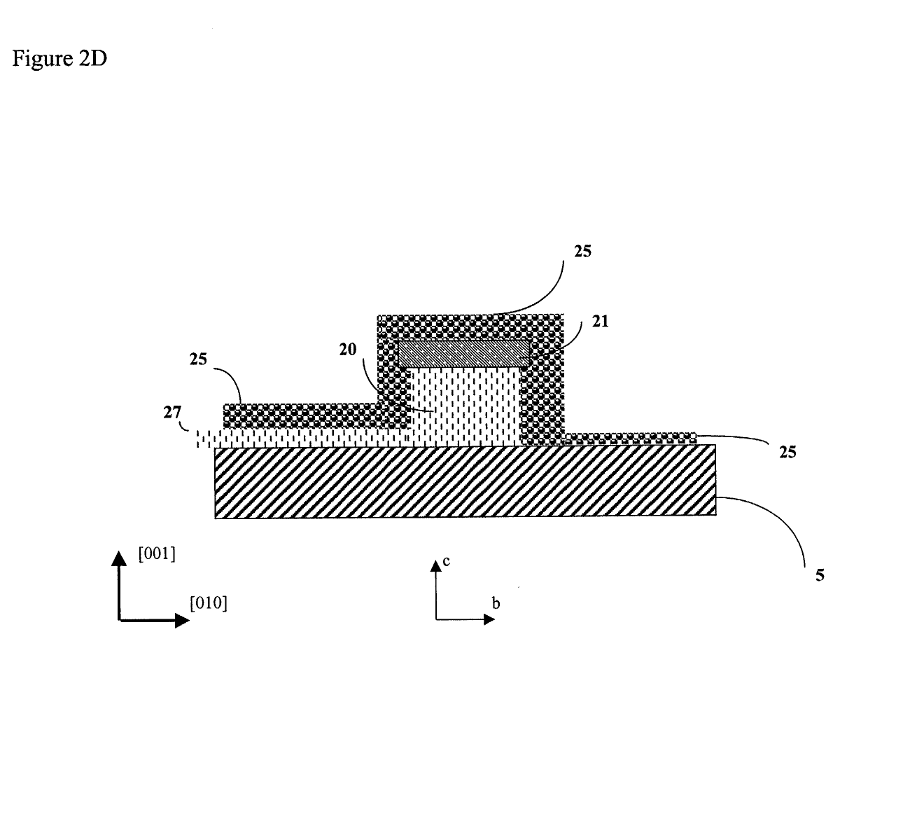

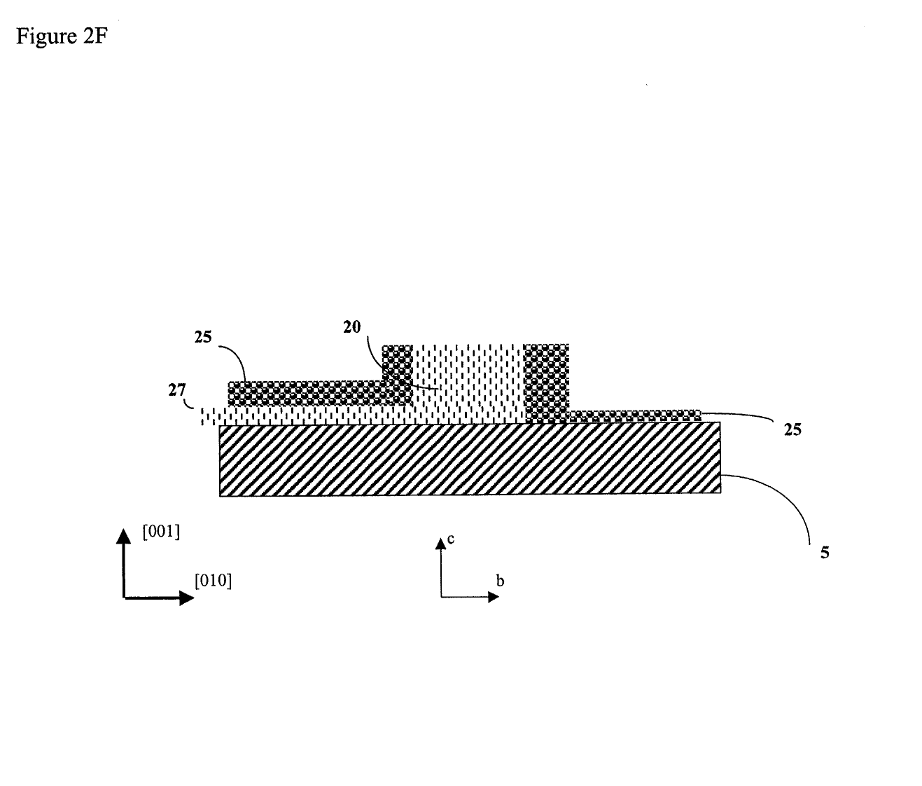

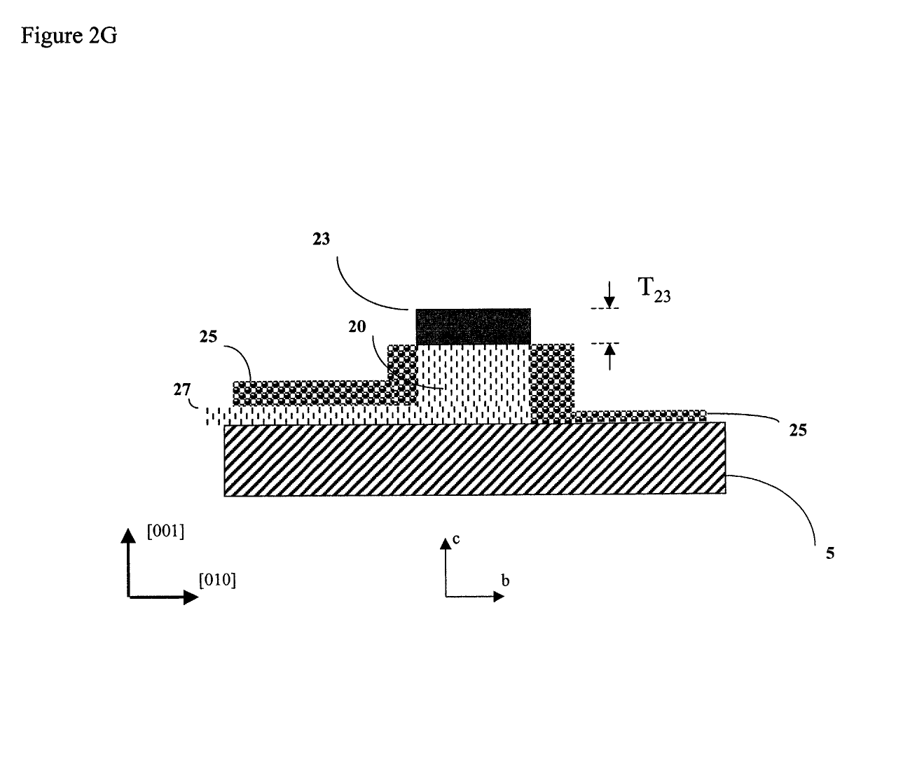

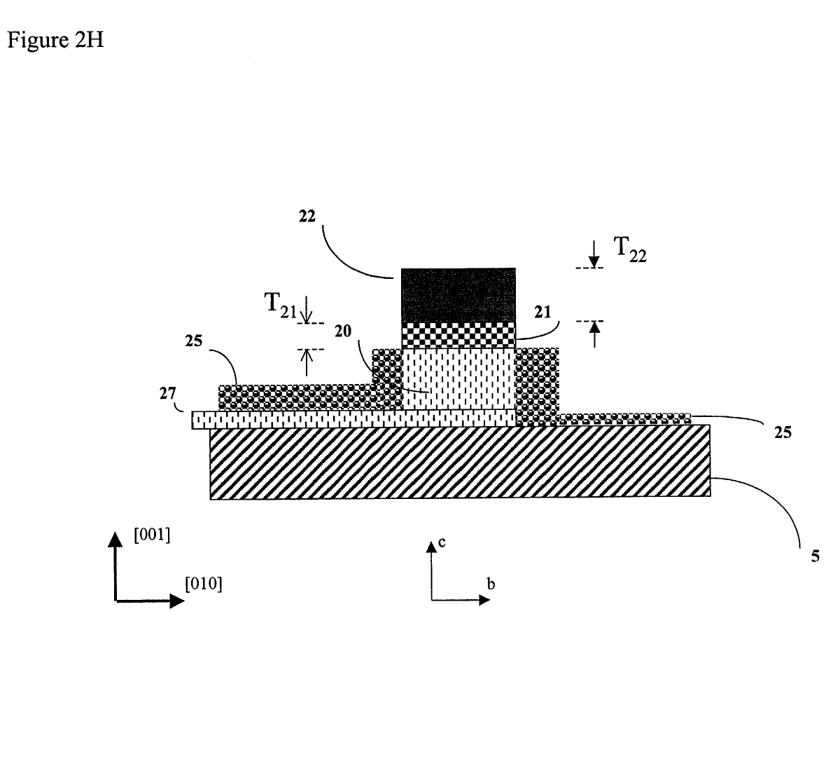

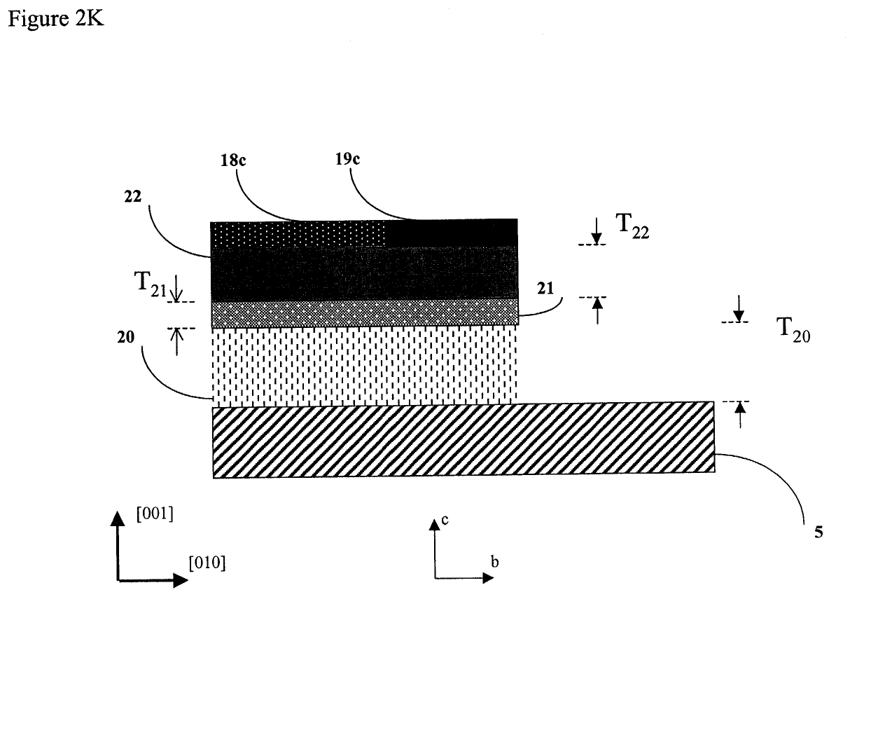

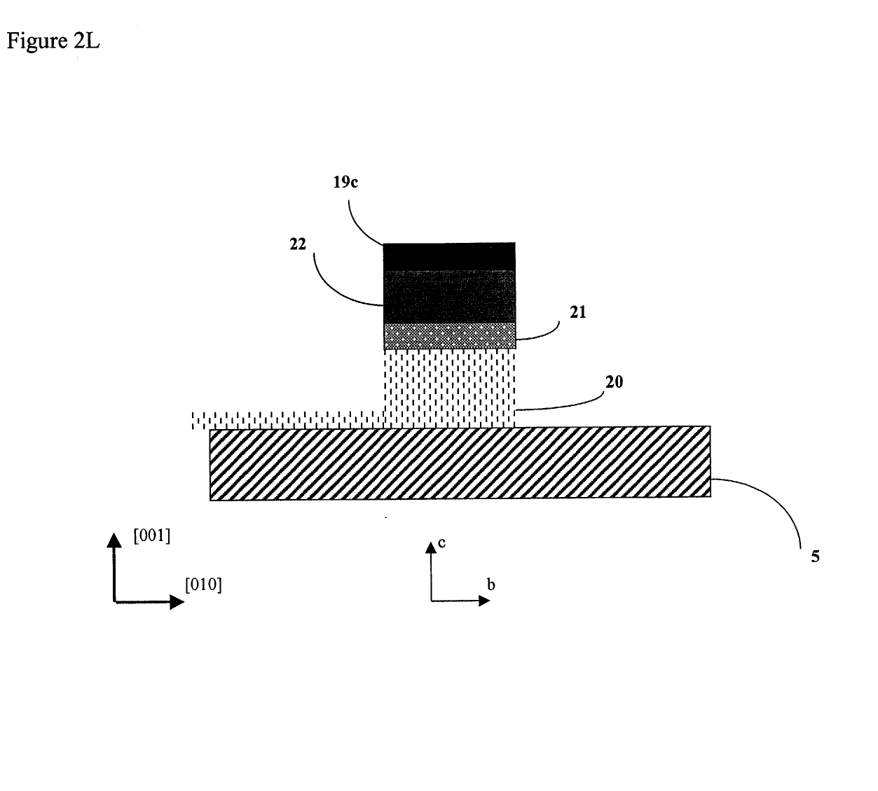

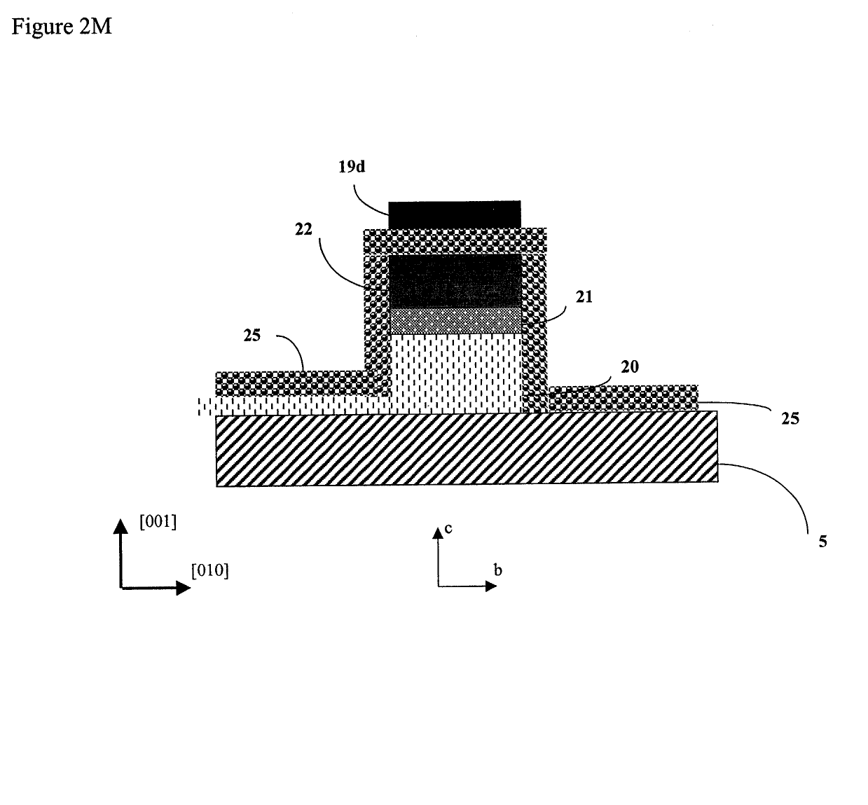

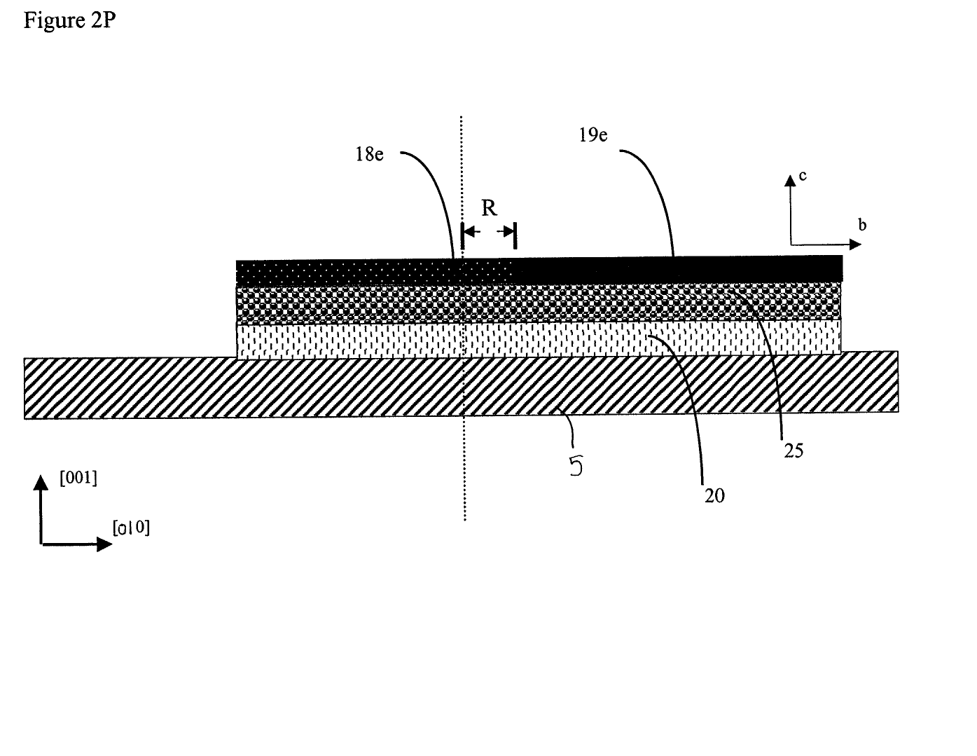

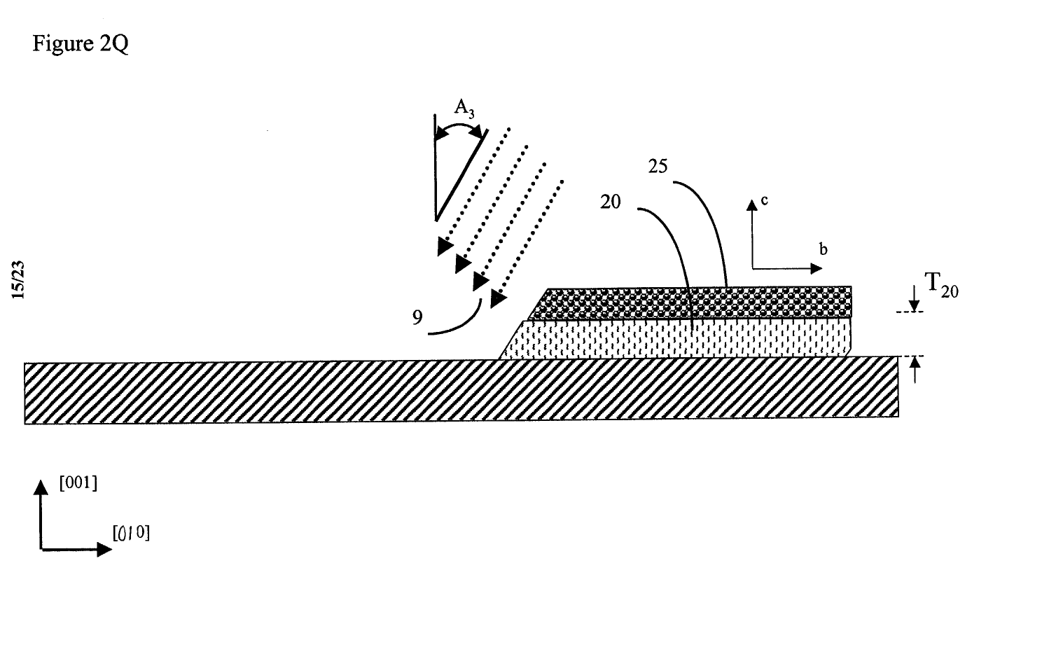

Embodiments of methods of fabricating the structures illustrated in FIGS. 1A-1C are illustrated below. FIGS. 2A-2D illustrate a method of fabricating a c-axis heterostructure as shown in FIG. 1A. FIGS. 2F-2H illustrate a method of fabricating any of the embodiments shown in FIGS. 1A-1C. FIGS. 2K-2M illustrate another method of fabricating a c-axis junction as shown in FIG. 1A. FIGS. 2P-2Q illustrate a method of fabricating an a-b plane junction as shown in FIG. 1B and a hybrid heterostructure as shown in FIG. 1C.

The general tools and techniques for depositing and patterning materials on a substrate are well known. One skilled in the art will recognize that tools and techniques other than those specifically discussed below may be used to fabricate the structures described in FIGS. 1A-1C. Any deposition and patterning techniques that achieve the same resulting structure can be considered. For example, J. M. Valles, Jr. et al, Phys. Rev. B 44, pp. 11986-11996 (1991), which is incorporated by reference, discuss methods of etching YBCO. YBCO crystals were etched “either in 10 mM HClO₄ and 1M NaClO₄ in water for 5-30 min. or 1.0% Br (by volume) in methanol for 30-120 min.” This yielded a smooth surface to which another material, such as the conventional superconductor lead, can be attached. The surface of an unconventional superconductor often has off stochiometric components and is locally depleted of oxygen. Etching creates a flat surface with a defined surface region that serves as an insulator for c-axis tunnel junctions. In some embodiments, these structures can be patterned using ion milling with anions or cations. This can be done with commercially available equipment. One such system is an Ar etching system produced by Sentech Instruments GmbH of Berlin, Germany. Photoresist masks are useful in some embodiments as they allow for precise placement of materials. EM and electron lithography can be used to shape the masks. Lithography is widely used in semiconductor manufacture and research. The ZBA e-beam series from Leica Microsystems AG of Wetzlar, Germany are suitable devices for some embodiments. Lastly, deposition of materials through effusion e.g. epitaxy, laser and thermal deposition, and sputtering allows for layers to be built upon the substrate. Submicron structures in High-T_{c} superconducting materials are described in P. Larsson, B. Nilsson, and Z. G. Ivanov, J. Vac. Sci. Technol. B 18, pp. 25-31 (2000); P. Larsson, A. Ya. Tzalenchuk, and Z. G Ivanov, J. Appl. Phys. 90, 3450 (2001), both of which are incorporated by reference.

Turning now to FIG. 2A, unconventional superconductor 20 is deposited on substrate 5. A layer of photoresist 18a and 19a is deposited over unconventional superconductor 20. Unconventional superconductor 20 may be patterned using the following well-known photolithography steps: application of photoresist layers 18a and 19a such as, for example, polymethylmethacrylate PMMA, selective exposure by, for example, UV, X-ray, or electron beam, developing (thermally or chemically) which removes a portion 18a of the photoresist and fixes another portion 19a, the mask. Either positive or negative photoresist may be used. Unconventional superconductor 20 may then be patterned by etching using, for example, a wet etch or a dry etch. The etching method used generally should not degrade the shape of the material being patterned nor alter its properties. Portions of the unconventional superconductor 20 are protected by the fixed resist 19a.

Optionally fabrication may include an intermediate mask made from gold and carbon to pattern the unconventional superconductor or any other layer. The methods are detailed in J. Vac. Sci. Technol. B 18, pp. 25-31 (2000) and J. Appl. Phys. 90, 3450 (2001) which have previously been incorporated by reference. In that case the pattern is transferred by ion etching such as an argon beam at 400 eV and 0.1 mA/cm² for 75 min through a 150-nm-thick carbon mask. While etching, the substrate may be thermally anchored to a water-cooled plate to avoid heating and degeneration of the unconventional superconductor. The in situ gold layer (approximately 20 nm thick) covering the unconventional superconductor may be removed by about 7 min of argon ion-beam etching at 400 eV and 0.1 mA/cm². The intermediate mask may be patterned by the use of a photoresist described above.

In FIG. 2B the portion of unconventional superconductor 20 underlying photoresist layer 19a remains at constant height T₂₀. The portion of the unconventional superconductor under photoresist layer 18a has been etched to thickness T₂₇. Photoresist layer 19a may then be removed. The material that later forms lead 27 is deposited at the same time as unconventional superconductor 20 to create a contiguous piece of material (i.e. no junction). In some embodiments, unconventional superconductor 20 is deposited at a thickness T₂₀ on the order of about 100 nm to about 200 nm. Lead portion 27 can have a thickness T₂₇ after patterning that is optionally less than T₂₀ and can be formed by, for example, the undercut resist lift off method which is known in the art see e.g. Born et al, IEEE Trans. Appl. Supercond. 11, pp. 373-376 (2001), which is incorporated by reference.

In FIG. 2C, a normal material layer 21 is deposited, then patterned with a photoresist layer 19b, such as, for example, PMMA. Normal material 21 is a conductor that is non superconducting at the operating parameters or an insulator. The parameters of the junction depend on the embodiment of the invention, but normal layer 21 can consist of a normal metal such as of gold (Au), silver (Ag), platinum (Pt), palladium (Pd) having a thickness T₂₁ less than about 20 nm. The thickness varies with coherence length of the superconductors or correlation length of the metal. Normal material 21 is patterned as shown in FIG. 2C. Normal material 21 is deposited on the entire structure, then photoresist 19b is fixed above a portion of normal material 21. Etching will create a bilayer, leaving only the portion of normal material 21 underlying photoresist layer 19b. Photoresist layer 19b may then be removed.

In some embodiments, an insulating layer 25, shown in FIG. 2D, is deposited over the structure shown in FIG. 2C. Insulating layer 25 may be deposited before or after the deposition of normal layer 21. Insulating layer 25 electrically isolates unconventional superconductor 20 and conventional superconductor 22 (see FIG. 1A). The thickness of such a layer may be enough to reduce the stray tunneling amplitude between unconventional superconductor 20 and conventional superconductor 22 to a negligible level. Insulator 25 may have a thickness several times the largest coherence length of the two superconductors 20 and 22. In other embodiments, rather than a normal metal, intermediate layer 21 is an insulating material, the same or different to insulating layer 25. Insulating layer 25 may be, for example, oxides of silicon or SrTiO₃. Insulating layer 25 is patterned to expose a portion of intermediate layer 21, on which conventional superconductor (FIG. 1A) is deposited.

A second superconductor 22 may then be deposited and patterned to yield the structure shown in FIG. 1A. Superconductor 22 may be a material with s-wave symmetry in the momentum space of its cooper pairs. Such a material in some embodiments can be lead (Pb), niobium (Nb) or aluminium (Al). Superconductor 22 can have thickness T₂₂ on the order of about 100 to about 300 nm. The consideration for selection of material may include the critical temperature T_{c} of the material, its defect density when patterned and its affinity to chemically react with the surrounding material. A lead 26 may be deposited on superconductor 22. Lead 26 can be of the same material as 22 or a different material, such as a normal metal. Lead 26 may be patterned at the same time as superconductor 22, or in separate etching steps.

FIGS. 2F-2H illustrate a method of fabrication that creates an insulator layer between the unconventional and conventional superconductors. This method can be used to create embodiments of the invention such as those shown in FIGS. 1A-1C and is similar to the method discussed in D. Racah et al, Physica C 263, pp. 218-224 (1996), which is hereby incorporated by reference in its entirety.

Referring now to FIG. 2F, an unconventional superconductor 20 is deposited on substrate 5 and patterned as described above in the text accompanying FIGS. 2A and 2B. Unconventional superconductor 20 may be an oxide with high oxygen mobility such as YBCO. A dielectric layer 25 may be deposited over unconventional superconductor 20 and patterned to expose a portion of unconventional superconductor 20.

As shown in FIG. 2G, above or adjacent to a smooth portion of unconventional superconductor 20, depending on the embodiment, a thin layer of oxygen receptor material 23, that is, a material with strong electronegativity, is placed. Material 23 accepts oxygen and forms an oxide which is intermediate layer 21. In one example, materal 23 is AL, which oxidizes to form and intermediate layer 21 of AlOₓ. In some embodiments, it may take tens of hours in a vacuum for layer 23 to spontaneously and completely oxidize. The natural oxygen mobility of oxide superconductors allows for the oxygen to diffuse in layer 23. Optionally, directly after the placement of oxide 23 a normal metal layer is deposited. This ensures that material 23 is oxidized to form intermediate layer 21 via diffusion from superconductor 20 and not by contact with the sparse atmosphere, and is not ablated in the process.

The thicker layer 23 is made, the lower the transparency of the junction, and the greater reduction in oxygen content of superconductor 20. For a volume ratio of about 10 for YBCO to Al this results in an under doping of about x=6.80 versus the optimal value for YBa₂Cu₃Oₓ of about x=6.94. The transparency can be addressed through limiting the thickness of material 23 or by introducing a thin noncontiguous normal metal layer between layer 23 and unconventional superconductor 20. The underdoping of the bulk can be corrected after manufacture by immersing the sample in an oxygen environment.

In FIG. 2H, precursor layer 23 of FIG. 2G has oxidized to form intermediate layer 21 with thickness T₂₁. The thickness may be about a few to tens of nanometers. Depositing and patterning a conventional superconductor 22 over intermediate material 21 yields a trilayer in the case of c-axis junctions. In some embodiments, the junction is able to transmit Cooper pairs. Racah et al. teach that these junctions should coincide with the well known properties of the oxide layer in conventional Al/AlOₓ/Al junctions. However no Josephson effect (Cooper pair tunneling) was observed in Racah et al.'s structures, only quasi particle tunneling.

In some embodiments, a thin layer of non-contiguous normal metal is inserted between oxidized material 21 and unconventional superconductor 20. Prior to the deposition of oxygen receptor layer 23, a small amount of metal such as Ag is deposited with a thickness less than 7 nm. The use of such a metal layer may increase the transparency of the junction. This layer may be deposited imperfectly with holes in it. Further, this method can be augmented chemical treatment as described in J. M. Valles, Jr. et al, cited above.

FIGS. 2K-2M illustrate yet another method of fabricating a c-axis junction such as that illustrated in FIG. 1A. An unpatterned deposited trilayer of first superconductor 20, intermediate material 21 and second superconductor 23 that has partial protection via a patterned and fixed resist 19c (shown in FIG. 2K) is etched by, for example, ion etching. In this embodiment, intermediate layer 21 may be a normal metal. The etching of the trilayer yields the elevation view of FIG. 2L. Note that the structure shown in FIG. 2L is most of the heterojunction 50 shown in FIG. 1A, with the exception of the optional insulation 25 and the top electrode 26. The fixing of electrodes can be accomplished by partially etching the first layer and using the reduced thin film as an electrode 27.

As shown in FIG. 2M, an insulating layer 25 may be placed directly on top of the structure shown in FIG. 2L, after photoresist 19c is stripped. A photoresist layer 19d is deposited and fixed to pattern the insulator 25. Cleaning of the sample may then remove photoresist 19d and a portion of insulator 25. Top electrode 26 can be affixed via patterning means discussed above. However, the contact area may be free of impurities. Electrode 26 may be the same material as conventional superconductor 22 or a different material such as a normal metal. The resulting structure is then junction 50 as illustrated in FIG. 1A.

FIGS. 2P-2Q illustrate a method of fabricating ramp-type junctions such as junctions 51 and 52, shown in FIGS. 1B and 1C. So called in the art, the ramp type junction was introduced by J. Gao et al Physica C 171, pp. 126-130 (1990), which is incorporated by reference. More familiar is the work of Smilde, et al, IEEE Trans. Appl. Supercond. 11, pp. 501-504 and the work of E. Il'ichev et al, App. Phys. Lett. 76, pp. 100-102 (2000), which are also incorporated by reference.

Unconventional superconducting layer 20 and insulating layer 25 are deposited on substrate 5. A photoresist may then be deposited, for example by spin deposition, then patterned. The photoresist is exposed to form fixed portion 19e and unfixed portion 18e. The interface between photoresist 18e and 19e is distance R from the normal from the point of the surface where the edge of unconventional superconducting layer 20 should be. Because of the differing etch rates of the materials underlying the photoresist, junctions with a non-zero angle with the substrate normal will form, as shown in FIG. 2Q. The bilayer is etched with ions 9 at an angle A3 with the substrate normal. Photoresist 1 9e is then removed.

The method illustrated in FIGS. 2P and 2Q can be applied to the hybrid structure of FIG. 1C by removing insulating layer 25 and increasing the areas of patterning for intermediate layer 21 and conventional superconductor 22.

Alternative embodiments of the invention can involve reversing the order of the two superconductor layers in the junctions shown in FIGS. 1A-1C. The term “SND” is defined as s-wave/normal/d-wave, with the s-wave layer closest to the substrate, and “SID” is defined as s-wave/insulator/d-wave, again with the s-wave layer closest to the substrate. In this invention the d-wave layer is not restricted to a d-wave superconductor; rather, any unconventional superconductor defined above as having non-zero angular momentum pairing, will yield the same effect. Traversing the heterostructure from the substrate out in the c-axis junction or right to left in the other embodiments is a SND or a SID structure. For the inverted trilayer the structure is DNS or DIS.

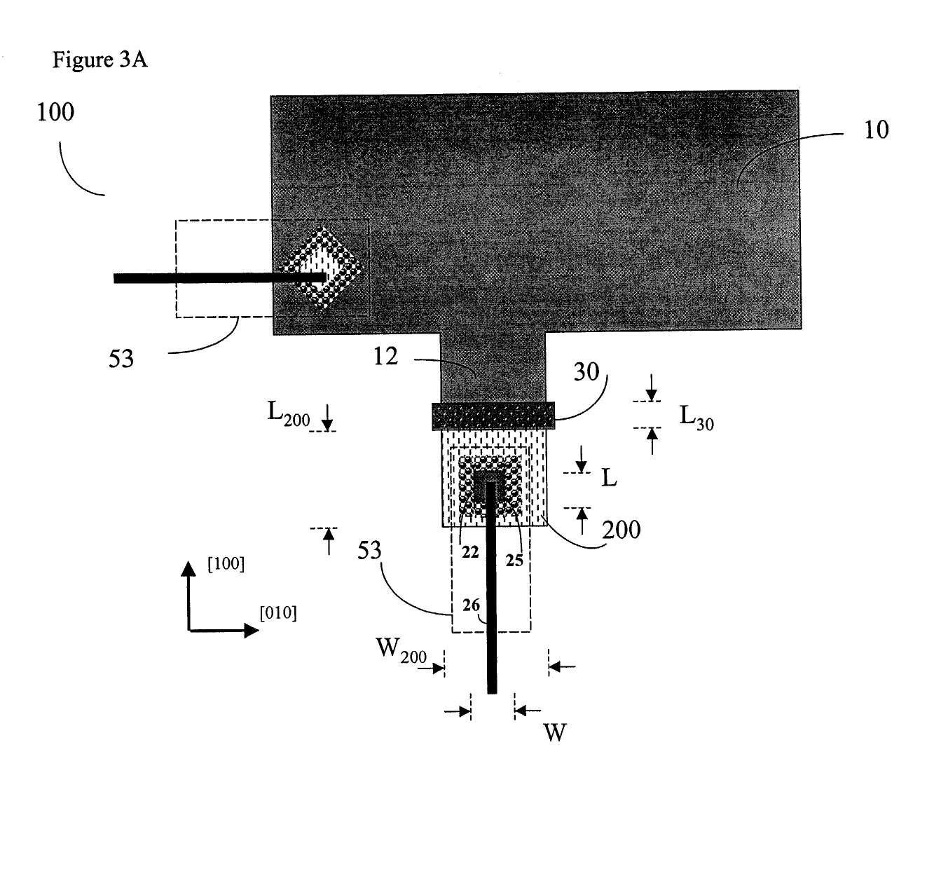

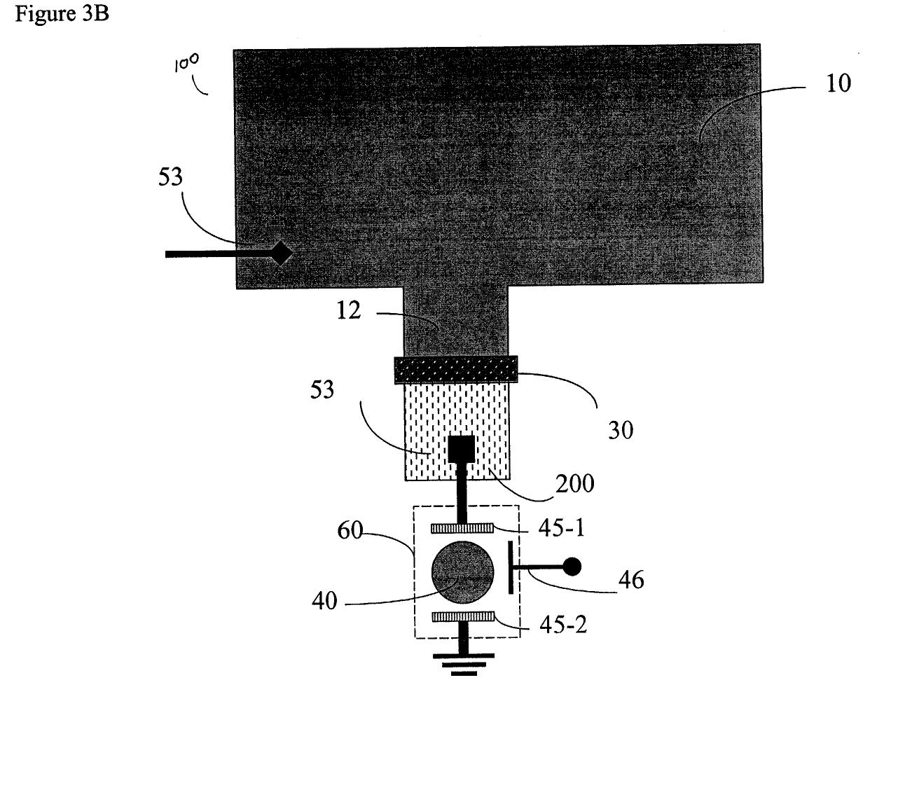

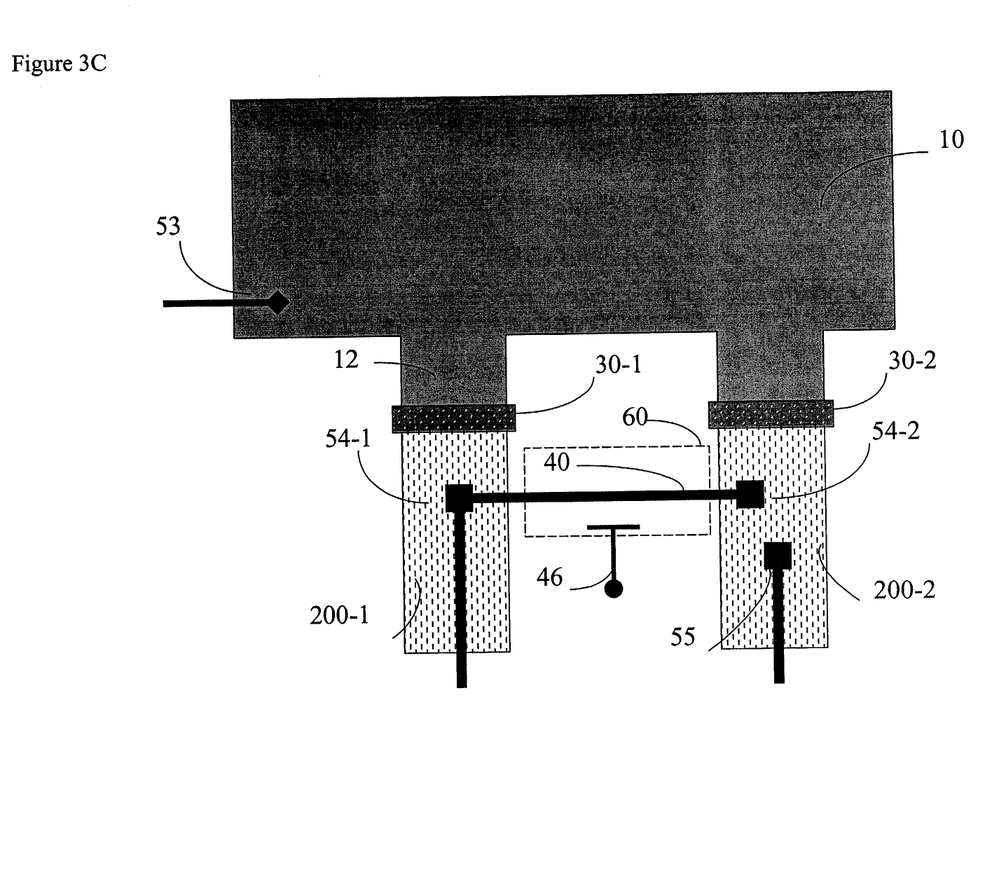

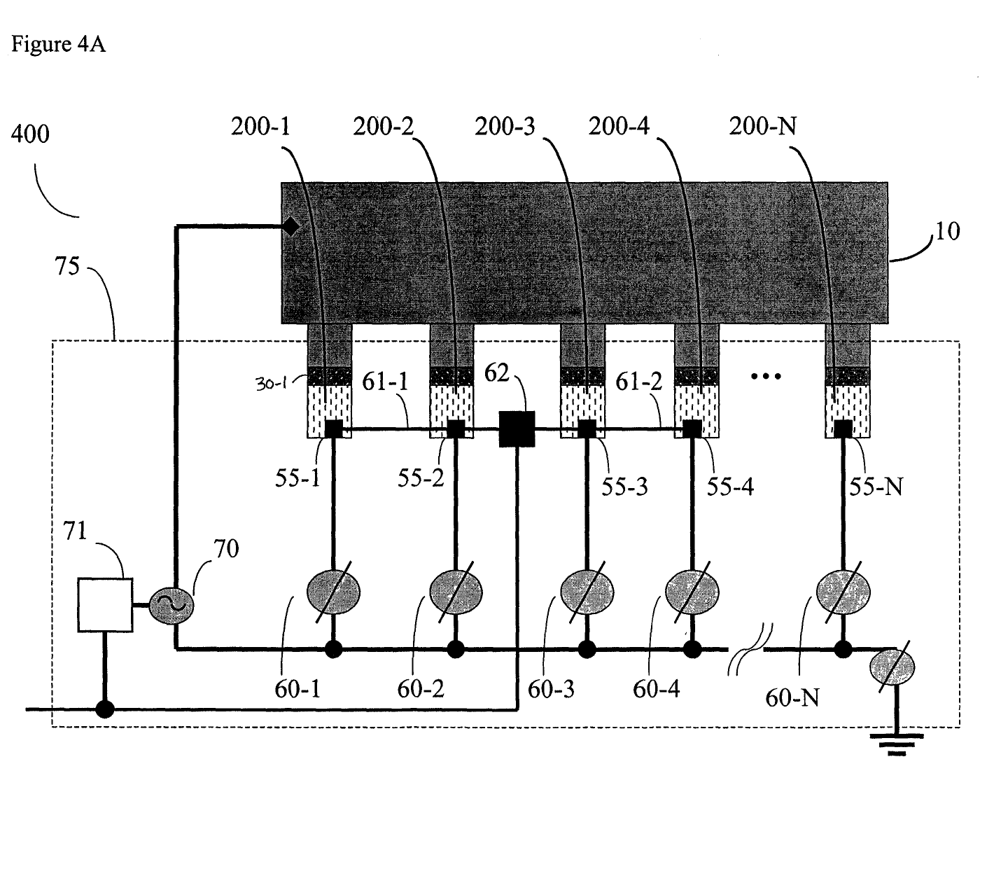

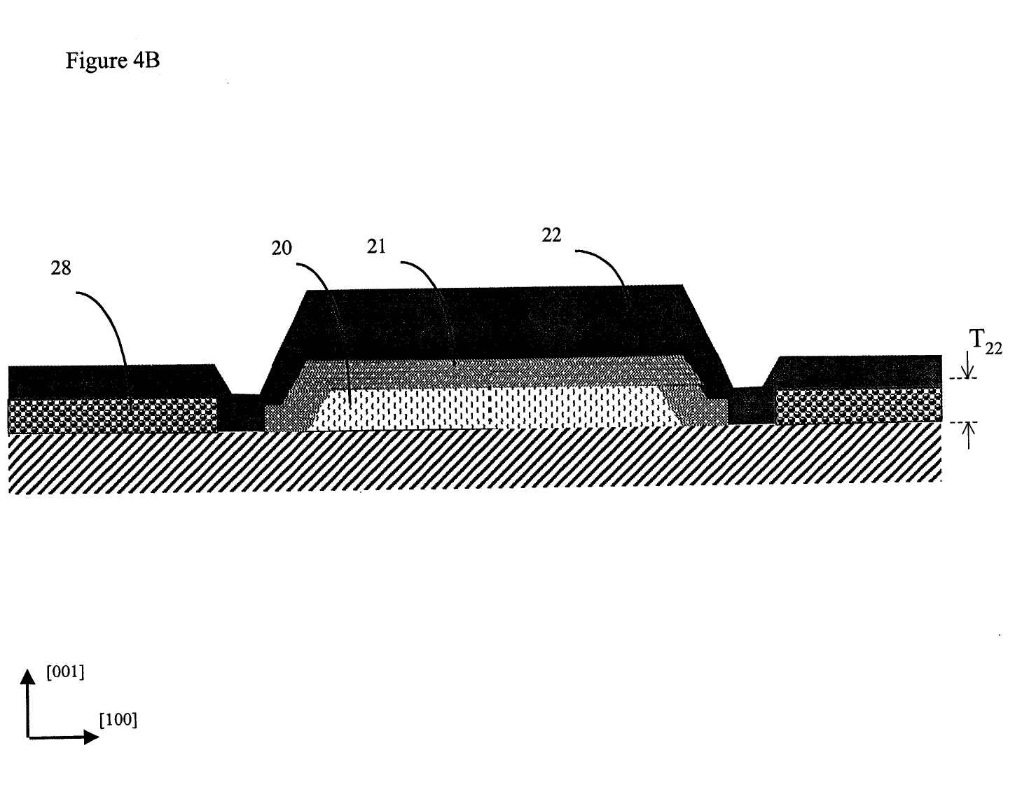

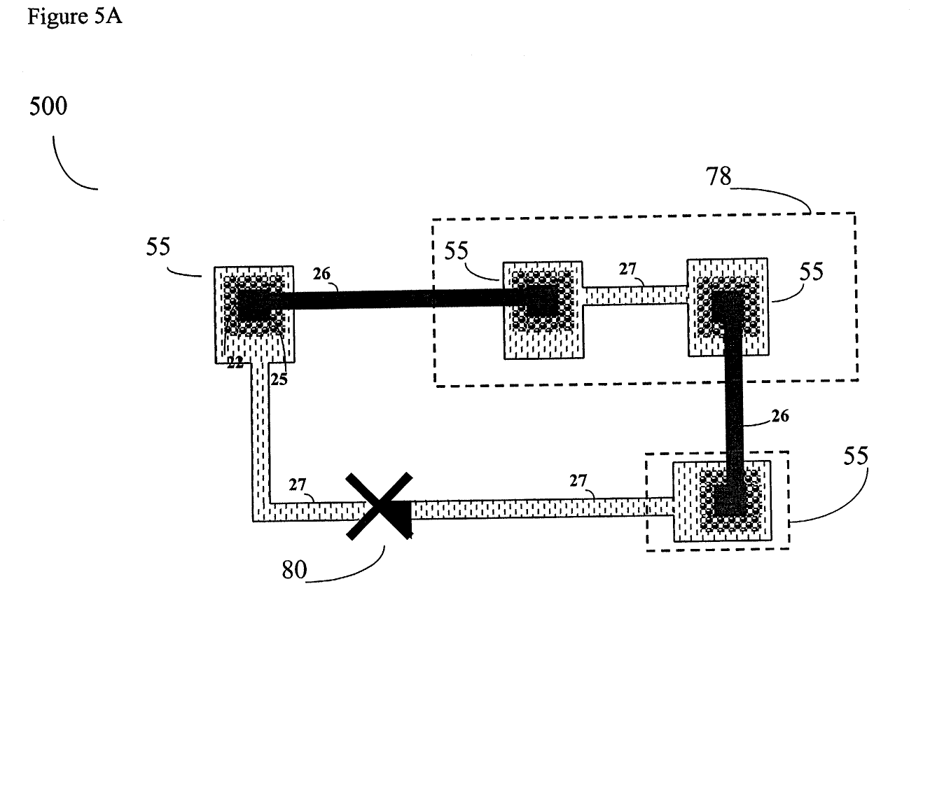

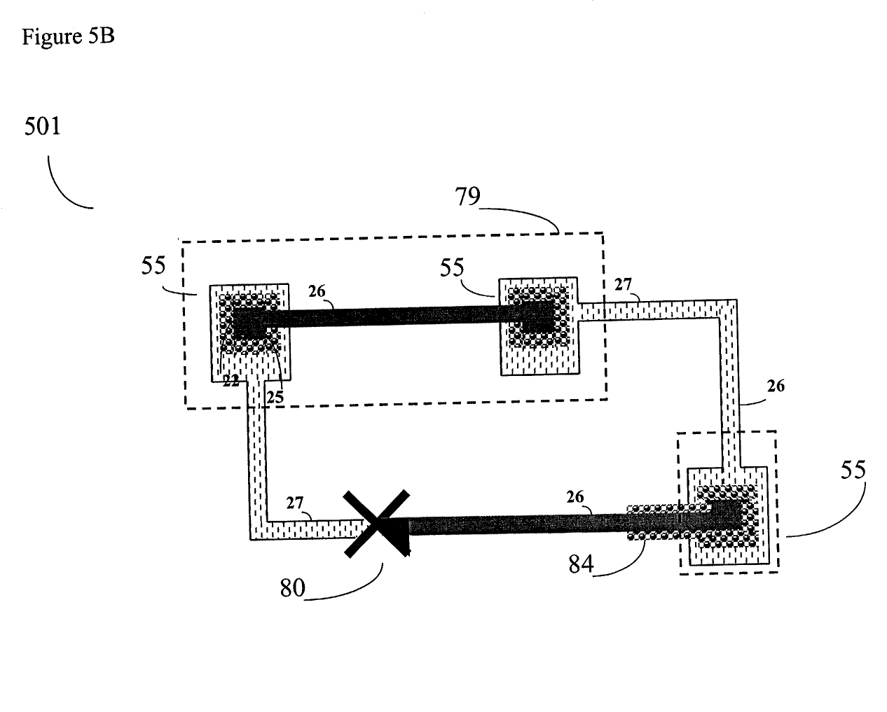

In FIGS. 3-6 the heterojunctions shown in FIGS. 1A-1C are presented in a series of applications. FIGS. 3A-3B incorporate an SND junction 53, which may be any of junctions 50, 51, or 52. FIG. 3C incorporates an SID junction 54, which may be any of junctions 50, 51, or 52. The junctions 55 incorporated into FIGS. 4, 5A, and 5B may be either SID or SND junctions, and may be any of junctions 50, 51, or 52.

FIG. 3A shows a junction, which may any of junctions 50, 51, or 52, affixed to a phase qubit. Qubits are described in more detail in application Ser. No. 09/479,336 titled “Qubit using a Josephson Junction between s-Wave and d-Wave Superconductors” filed Jan. 7, 2000; application Ser. No. 09/872,495 titled “Quantum Processing System and Method for a Superconducting Phase Qubit” filed Jun. 1, 2001; and application Ser. No. 60/316,134 titled “Superconducting Low Inductance Qubit” filed Aug. 29, 2001, each of which is incorporated by reference. For illustrative purposes the phase qubit 100 is shown as a permanent readout superconducting qubit (PRSQ). A bank of superconducting material 10 has an optional finger 12. It is separated from a mesoscopic island 200 via a junction 30, which may be any of the junctions shown in FIGS. 1A-1C above, with length L30. The relative phase of bank 10 to island 200 form the bit states of the phase qubit.

The phase qubit 100 could be any qubit including a micrometer sized loop with several Josephson junctions and a radio frequency SQUID. Alternatively qubit 100 could be a super low inductance qubit (SLIQ). The SLIQ is a loop interrupted by one π/2 junction and two other Josephson junctions. Its bit state is based on phase as with the PRSQ and is detected via differentiable antiparallel magnetic fields in the plan of the substrate.

Junctions 53 attached to island 200 and bank 10 are inverse (or reflected) trilayers to each other. This may be done because in the given example of the PRSQ, bank 10 may be formed of the same material as conventional superconductor 22 and island 200 may be formed of the same material as unconventional superconductor 20 of FIGS. 1A-1C. Embodiments of the PRSQ may have the materials reversed.

The relative size of junction 53 and island 200 is not as drawn. Junction 53 need not be smaller than island 200. However gross mismatch in size may not be desirable as the smaller of island 200 and junction 53 will dictate operational parameters.

FIG. 3B shows a phase qubit 100 with an optional parity key 60 attached. One embodiment of a parity key is a superconducting single electron transistor (SET). SETs are well known and described, for example, by A. Zagoskin, Quantum Theory of Many-Body Processes, Springer-Verlag (1997), which is incorporated by reference. SETs include an island 45 capacitively coupled to three devices, qubit island 200, gate electrode 46, and ground. An electron or Cooper pair can tunnel from island 200 onto island 40 when island 40 is uncharged. However, island 40 is small enough that once an electron or Cooper pair tunnels onto it, the charging of island 40 electrically repels and prevents further tunneling onto island 40. A gate 46 can change the voltage of island 40 to shut off or otherwise control the tunneling rate. SETs have a charge energy that is in excess of 10 times the Josephson energy. P. Joyez et al, Phys. Rev. Lett. 72:15 (1994), which is incorporated by reference, describes operation and manufacture of one type of SET.

Parity key 60 is introduced as part of a control system process optionally used to fix the state of the qubit or to create quantum entanglements between qubits. Fixing the state of the qubit is accomplished by connecting a qubit to ground as illustrated in this example. Creating entanglements between qubits is accomplished through connections between qubits. Embodiments of the parity key can be made from a conventional superconductor or an unconventional superconductor, hence the need for a heterojunction connection between phase qubit 100 and parity key 60. Phase qubit island 200 may be made of unconventional superconductor and parity key 60 may be made of a conventional superconductor, or vice versa, which can be labeled a SIS SET. This is done because the capacitive is an insulating layer. Traversing from island 200 to ground for this example one encounters the following order of materials DNSISIS. The SISIS is structure is parity key 60. The middle S in “SISIS” is island 40 of the SET. The DNS structure is junction 53.

FIG. 3C introduces a DISID parity key 60 connecting two qubits. Heterojunctions 54 are affixed as described above. Island 40 of the SET is now the entire electrode that joins heterojunctions 54. The SET has a gate electrode 46. The acronym DISID is easy to deduce by traversing from island 200-1 through to island 200-2. Parity key 60 is comprised of island 40 and gate 46. Island 40 is a conventional superconducting material and is voltage biased, meaning that the current through the device is controlled through differing voltages on electrode 46. The voltage level of electrode 46 determines whether any current flows or quasi particle or Cooper pairs flow. Alternatively, flux modulated switches could be employed. Flux modulated switches operate on the principle of using a flux that threads a loop to control current. See, for example, G. Schön et al Rev. Mod. Phys. 73 pp.357-400 (2001), which is incorporated by reference.

In addition to the reduction in scale of the interface between island 200 and junction 54, detailed above, other dimensions are important to the operation of the PRSQ. The size of junction 54 is related to the consideration of the charging energy and Josephson energy, which depend on capacitance and transparency. The charging energy is inversely proportional to capacitance and hence area, while the Josephson energy is directly and independently proportional to transparency and area. The transparency of c-axis junctions, regardless of whether the junction is SID or SND, is very small. Therefore, it would be necessary to make the area of c-axis junctions slightly larger than a-b plane junctions. This yields a quadratic, in terms of area, increase in the ratio of the Josephson energy to charging energy. Too large a ratio is not useful for parity keys. The size of junctions 54 is not unbounded; there exist an area where the charging energy is of a sufficient level without the Josephson energy being too small.

Careful consideration of the effect of affixing heterojunction 54 on island 200 must be considered. The size of junctions 54 is not unbounded as the dimensions of islands 200 are dictated by the embodiment of the PRSQ, and should be mesoscopic. In general, mesoscopic means:

a class of solid systems where the single particle approach holds and gives sensible results, namely, the mesoscopic systems (see, e.g., Imry 1986). These are the systems of intermediate size, i.e., macroscopic but small enough (≦10⁻⁴ cm). In these systems quantum interference is very important, since at low enough temperatures (<1K) the phase coherence length of quasiparticles (“electrons”) exceeds the size of the system.

Page 19 of Alexandre Zagoskin, Quantum Theory of Many Body Systems, (Springer 1998), previously incorporated, citing Y. Imry, “Physics of Mesoscopic Systems”, in Directions in Condensed Matter Physics: Memorial Volume in Honor of Shang-Keng Ma (ed. G. Grinstein, G. Mazenko, World Scientific 1986). The major contribution to the capacitance in a PRSQ is given by Josephson junction 30, which in turn is determined by the width W₂₀₀, not the length L₂₀₀, of island 200. There is a limit on the length, above which the island is no longer mesoscopic, which depends on the embodiment. The islands can be made narrower, but long, increasing the surface available for the c-axis junction. The larger area junctions will increase capacitance and lower the charging energy of junction 54. However, the addition of junction 54 to island 200 will increase the capacitance of island 200 and decrease its charging energy, especially for SID junctions. This will result in a smaller plasma frequency and a smaller tunnel splitting between the eigenstates affecting the operation of the qubit, which is not desired when creating a qubit.

Balancing all concerns, interface areas of island 200 and junction 54 of about 0.1 μm in width to about 0.5 μm or longer in length for a c-axis junction and less for an a-b plane junction, are appropriate sizes for a PRSQ. The situation is less severe in the case of SND junctions, where the normal metal can be thicker, resulting in a lower capacitance.

The purpose of connecting the qubits is to entangle them. This allows for the wave function of the individual qubits to overlap. Information may then be exchanged between qubits. The parity key with controllable single particle tunneling is an effective way to couple and de-couple qubits.

FIG. 4A shows embodiments of the invention as applied to a quantum register. FIG. 4B illustrates a cross section of a portion of the device shown in FIG. 4A. The substrate to which junctions 55 and parity keys 60 are affixed is a pattern bank 10, and islands 200 of a PRSQ. Prior to the placement of the heterojunctions, an insulating layer 28 shown in FIG. 4B is formed over islands 200 and patterned to form a series of holes. In the holes of the insulator, the intermediate layers of junctions 55 are placed, as illustrated in FIG. 4B.

As depicted only a small region around each island 200 is exposed. Insulator 28 covers the rest of the chip. Using the methods described above the exposed portion is filled with a normal material, followed by superconductor layer 22. Intermediate layer 21 may fill the hole in layer 28. The bistable Josephson junction 30 of register 400 is not in contact with layer 21. Further intermediate layer 21 has both a-b plane and c-axis contact with island. Intermediate layer 21 may be a normal metal.

A simple lead 61 may permanently connect two physical qubits creating one logical qubit. The qubits of the quantum register can be linked to a control system similar to the one found in U.S. application Ser. No. 09/872,495, titled “Quantum Processing System And Method For A Superconducting Phase Qubit” and incorporated herein by reference. The major elements of such a control system are a manner to bias the bank 10 through junctions 55 via a variable power source 70, a readout sensor 62, and generalized control system 71 connected to sensor 62 and power source 70 with leads off the register.

FIG. 5A shows a plan view of an even number of interface junctions connected by electrodes 26 and 27 to a Josephson junction 80. The placement of the insulator 25 separates electrodes 26 and 27. In some examples electrodes 26 and 27 are in a vertical structure separated by insulator 25. Heterojunctions 55 may be added to this system in pairs 78. For simplification of discussion of this example pair 78 is treated as a single contiguous electrode 26. An equally valid example is to have any even number of interface junctions in structure 78. The last component of system 400 is Josephson junction 80. Junction 80 can be a junction with an intrinsic phase shift across it (Δφ=[0,π]) formed with unconventional superconducting material leads. Junction 80 could have the maximal intrinsic phase shift across it. For an example of a π junction see R. R. Schulz et al, Appl. Phys. Lett. 76, 912 (2000), which is incorporated by reference. This can be accomplished through multiple means. One method is to frustrate junction 80 by threading an external magnetic flux through the loop as proposed by Mooij et al, Science 285, pp.1036-1039 (1999), which is incorporated by reference. In this example the phase shift is π/2 and is created by forming a 45° grain boundary junction by patterning an unconventional superconductor such as YBCO over a grain boundary of a bicrystal. There are other means to create (Δφ=[0,π]) junctions 80 such as biepitaxial methods, see S. Nicoletti et al, Physica C 269, 255 (1996), which is incorporated herein by reference.

Interface junctions can be formed to link a series of junctions with electrodes of alternating materials. The relative energies of the junctions can be made the same for the interface junctions 55 and much less for the π junction 80. This would be done to avoid Aharonov-Casher interference effects that would occur in a loop with junctions 55 and 80 all having the same Josephson energy, see Blatter et al, Phys. Rev. B 63, pp. 174511:1-7 (2001), which is incorporated herein by reference.

FIG. 5B shows the use of a insulating ramp 84 to yield an odd number of interface junctions placed in a loop with a π/2 junction 80. In this example π/2 junction 80 has two leads made of different types of superconductors: one of an unconventional superconductor and the other of a conventional. Ramp 84 is an insulator and allows electrode 27 from the base of pair 79 to become the top electrode 26 of heterojunction 55. The number of interface junctions 55 in pair 79 need only be even (or zero). The number of interface junctions in the loop 501 is odd. In some embodiments, junctions 55 of FIGS. 5A and 5B are SND c-axis junctions.

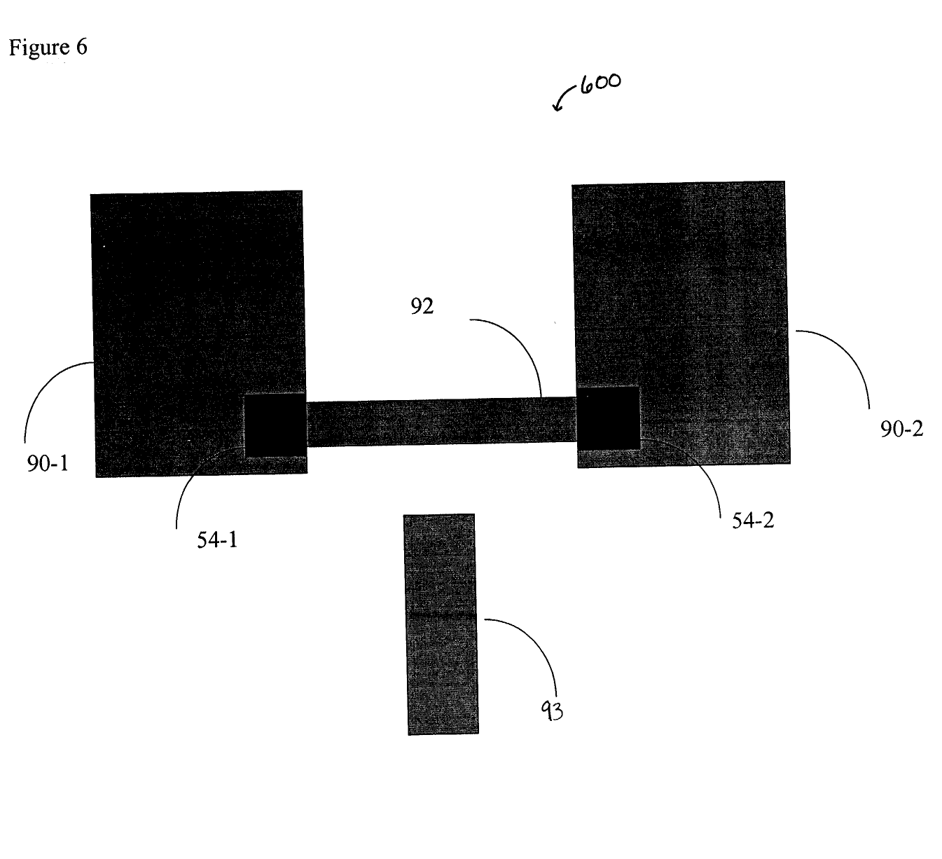

FIG. 6 illustrates a parity key incorporating embodiments of the present invention. A region of conventional superconductor 92 is capacitively coupled, via junctions 54, to two regions of unconventional superconductor 90-1 and 90-2, and to an optional gate electrode 93. The right combination of junction size and material used may create a coherent connection between unconventional regions 90, enabling phase-preserving transport between unconventional regions 90. Conventional region 92 is generally of mesoscopic size to ensure phase coherency. Junctions 54 may be, for example, any of the junctions shown in FIGS. 1A-1C, and generally have an insulator or a combination of insulator and normal metal as an intermediate material between the conventional and unconventional superconductors.

A voltage applied to gate 93 can alter the energy of conventional region 92 by capacitive coupling, allowing Cooper pairs to flow between unconventional regions 90. Optional gate electrode 93 need not be superconducting, but may be a conventional superconductor. The flow of Cooper pairs and electrons may be modulated by the application of different voltages to gate 93. The charging energy of conventional region 92 may also be controlled by controlling the capacitance of junctions 54, allowing Cooper pairs to flow in the absence of an applied voltage. Thus, in some embodiments, gate 93 is optional.

Although the invention has been described with reference to particular embodiments, the description is only examples of the invention's applications and should not be taken as limiting. Various adaptations and combinations of features of the embodiments disclosed are within the scope of the invention as defined by the following claims.

What is being claimed is:

1. A Josephson junction comprising:
a substrate;
a first superconducting material layer overlying the substrate;
an intermediate layer overlying at least a portion of the first superconducting material layer; and
a second superconducting material layer overlying at least a portion of the intermediate layer and at least a portion of the first superconducting material layer;
wherein an area of the first superconducting material layer underlying the second superconducting material layer is less than or equal to about 0.1 μm².

2. The Josephson junction of claim 1 wherein:
the first superconducting material is a crystalline material having an orthorhombic crystal structure comprising an a-axis, a b-axis, and a c-axis, the c-axis comprising the largest lattice vector;
the c-axis makes a first angle to a plane normal to the substrate; and
the a axis makes a second angle to a plane normal to the substrate.

3. The Josephson junction of claim 2 wherein the first angle is between about zero and about ninety degrees.

4. The Josephson junction of claim 2 wherein an area of the first superconducting material layer underlying the second superconducting material layer has a length and a width, the width being less than the length.

5. The Josephson junction of claim 4 wherein:
a first surface of the first superconducting material layer forms a first facet;
the first facet makes a third angle to a plane normal to the substrate; and
a second surface of the first superconducting material layer forms a second facet substantially parallel to a surface of the substrate.

6. The Josephson junction of claim 5 wherein the third angle is between about zero and about ninety degrees.

7. The Josephson junction of claim 5 wherein the third angle is about thirty degrees.

8. The Josephson junction of claim 5 wherein:
a first portion of the second superconducting material layer is adjacent to the substrate; and
a second portion of the second superconducting material layer overlies the first facet of the first superconducting material layer.

9. The Josephson junction of claim 8 wherein a portion of the first superconducting material layer underlying the second portion of the second superconducting material layer has length of about 0.2 μm and a width of about 0.1 μm.

10. The Josephson junction of claim 5 wherein:
a first portion of the second superconducting material layer is adjacent to the substrate;
a second portion of the second superconducting material layer overlies the first facet of the first superconducting material layer; and
a third portion of the second superconducting material layer overlies the second facet of the first superconducting material layer.

11. The Josephson junction of claim 5 wherein a portion of the second superconducting material layer overlies the second facet of the first superconducting material layer.

12. The Josephson junction of claim 11 wherein a portion of the first superconducting material layer underlying the portion of the second superconducting material layer has length of about 0.5 μm and a width of about 0.1 μm.

13. The Josephson junction of claim 1 wherein the first superconducting material has a dominant anisotropic order parameter.

14. The Josephson junction of claim 1 wherein the first superconducting material has non zero angular momentum pairing.

15. The Josephson junction of claim 1 wherein the first superconducting material is a d-wave superconductor.

16. The Josephson junction of claim 1 wherein the first superconducting material is YBa₂Cu₃Oₓ.

17. The Josephson junction of claim 1 wherein the second superconducting material is an s-wave superconductor.

18. The Josephson junction of claim 1 wherein the second superconducting material is selected from the group consisting of lead, niobium, and aluminum.

19. The Josephson junction of claim 1 wherein the intermediate layer is a normal metal.

20. The Josephson junction of claim 1 wherein the intermediate layer is selected from the group consisting of gold, silver, platinum, and palladium.

21. The Josephson junction of claim 1 wherein the intermediate layer is an insulator.

22. The Josephson junction of claim 1 wherein the intermediate layer is a mixture o f an insulator and normal metal.

23. The Josephson junction of claim 1 wherein an area of the first superconducting material layer underlying the second superconducting material layer is between about 0.01 μm² and about 0.1 μm².

24. The Josephson junction of claim 1 wherein an area of the first superconducting material layer underlying the second superconducting material layer is of mesoscopic size.

25. The Josephson junction of claim 1 wherein the first superconducting material layer has a thickness between about 75 nm and about 200 nm.

26. The Josephson junction of claim 1 wherein the second superconducting material layer has a thickness between about 100 nm and about 300 nm.

27. The Josephson junction of claim 1 wherein the intermediate layer has a thickness between about 1 nm and about 20 nm.
